(19) United States
(12) Patent Application Publication
(10) Pub. No.: US 2014/0265562 A1
(43) Pub. Date: Sep. 18, 2014

(54) APPARATUS FOR PROTECTING AGAINST THEFT OF ELECTRICITY FROM DISTRIBUTION TRANSFORMERS

(71) Applicant: MOLONEY ELECTRIC INC., Toronto (CA)

(72) Inventor: Robert Eugene Thompson, Burlington (CA)

(73) Assignee: MOLONEY ELECTRIC INC., Toronto (CA)

(21) Appl. No.: 13/836,278

(22) Filed: Mar. 15, 2013

(51) Int. Cl. H02J 4/00; G01R 21/00

(52) U.S. Cl. CPC H02J 4/00; G01R 21/00
USPC 307/17; 324/76.11; 29/402.01

(57) ABSTRACT

Disclosed herein is an apparatus for protecting against theft of electricity from a distribution transformer that transforms electricity from a higher distribution voltage to a lower secondary voltage. The distribution transformer is housed in a transformer housing having secondary terminals extending therefrom. The apparatus includes a protective enclosure rigidly attachable to an outer portion of the transformer housing adjacent the secondary terminals. The protective enclosure is configured to enclose the secondary terminals and to house a plurality of electricity meters for measuring electricity usage. The protective enclosure also has a plurality of service line apertures sized and shaped to receive a plurality of secondary service lines therethrough. Each secondary service line is electrically connectable to one of the electricity meters. The apparatus also includes a secondary bus line located within the protective enclosure for electrically connecting the secondary terminals to the plurality of electricity meters.

### TECHNICAL FIELD

The embodiments disclosed herein relate to apparatus for delivering electricity from a high voltage distribution line to a building, and in particular, to apparatus for protecting against theft of electricity from secondary service lines that provide electricity to the buildings.

### BACKGROUND

Electrical utilities throughout the world lose millions of dollars due to non-technical loses. Non-technical loses are often a result of electricity theft, which is a growing problem, especially in developing countries such as Jamaica, Puerto Rico, Dominican Republic, and India, among other countries. In some cases, electricity theft can represent a considerable expense. For example, in 2011, Jamaica estimated that electricity theft amounted to approximately 11.8% of total electricity losses throughout the country.

A common form of electricity theft occurs after power is stepped down from a high voltage distribution line to a lower voltage secondary service line that provides electricity to buildings such as houses and businesses. Specifically, an unauthorized line is connected to an “open secondary”, i.e. a secondary service line that is easily accessible to occupants of the buildings. Common access points for theft include the point at which the secondary service line enters a building, or at the overhead wires near the transformer.

Electricity meters can be installed to measure the amount of power passing through the secondary service line. This enables the power company to track the actual amount of power consumed downstream of the electricity meter, including electricity being stolen from a connection downstream of the electricity meter. However, there are ways to circumvent these electricity meters. For example, it is possible to by-pass the electricity meter by making an unauthorized connection upstream of the electricity meter, in which case, the electricity theft cannot be detected because it is stolen prior to being measured by the electricity meter.

In order to counteract this type of theft, some meters are installed on utility poles near the overhead high voltage distribution lines. Mounting the meters higher up can make it more difficult to bypass the meter. However, even with the electricity meters placed high up in the air, theft is still possible because there remains an open secondary between the transformer and the meter.

### SUMMARY

According to some embodiments, there is an apparatus for protecting against theft of electricity from a distribution transformer that transforms electricity from a higher distribution voltage to a lower secondary voltage. The distribution transformer is housed in a transformer housing having secondary terminals extending therefrom. The apparatus includes a protective enclosure rigidly attachable to an outer portion of the transformer housing adjacent the secondary terminals. The protective enclosure is configured to enclose the secondary terminals and to house a plurality of electricity meters for measuring electricity usage. The protective enclosure also has a plurality of service line apertures sized and shaped to receive a plurality of secondary service lines therethrough. Each secondary service line is electrically connectable to one of the electricity meters. The apparatus also includes at least one secondary bus line located within the protective enclosure for electrically connecting the secondary terminals to the plurality of electricity meters.

The protective enclosure may also include a meter housing having an interior meter chamber configured for housing the electricity meters. The meter housing also has opening in a back side thereof. The protective enclosure also includes a throat extending outwardly from the back side of the meter housing around the opening to the outer portion of the transformer housing. The throat may be configured to provide an enclosed passageway between the secondary terminals and the meter chamber for receiving the secondary bus line therethrough.

The protective enclosure may also include a mounting structure for mounting the plurality of electricity meters within the meter housing.

The throat may space apart the transformer housing from the meter housing, and the protective enclosure may include a support bracket offset from the throat for securing the transformer housing to the meter housing.

The throat may have a first end mounted to the transformer housing, and a second end with a flange mounted to the meter housing. The first end may be welded to the transformer housing. The flange may be secured to the meter housing using fasteners. The apparatus may also include a gasket between the second flange and the meter housing.

The protective enclosure may include an access door for providing access to the electricity meters, and an anti-tampering device for restricting unauthorized opening of the access door. The anti-tampering device may include a lock for closing the access door. The anti-tampering device may include a sensor for detecting unauthorized opening of the access door.

The apparatus may include a disconnect switch operatively connected to the anti-tampering device. The disconnect switch may be configured to disconnect power to a downstream location when the anti-tampering device detects unauthorized opening of the access door.

According to some embodiments, there is an apparatus for delivering electricity from a high voltage distribution line to a plurality of buildings. The apparatus includes a distribution transformer for transforming electricity from a higher distribution voltage to a lower secondary voltage. The distribution transformer is housed in a transformer housing having secondary terminals extending therefrom. The apparatus also includes a protective enclosure rigidly attachable to an outer portion of the transformer housing adjacent the secondary terminals. The protective enclosure is configured to enclose the secondary terminals and to house a plurality of electricity meters for measuring electricity usage. The protective enclosure has a plurality of service line apertures sized and shaped to receive a plurality of secondary service lines therethrough. Each secondary service line is electrically connectable to one of the electricity meters. The apparatus also includes at least one secondary bus line located within the protective enclosure for electrically connecting the secondary terminals to the plurality of electricity meters.

According to some embodiments, there is a method of refurbishing a pre-existing transformer housing to deter theft of electricity. The pre-existing transformer housing has a distribution transformer therein for transforming electricity from a higher distribution voltage to a lower secondary voltage and a plurality of secondary terminals extending from the pre-existing transformer housing. The method includes dismounting the pre-existing transformer housing from a utility pole, disassembling the pre-existing transformer housing and removing the distribution transformer therefrom, and rigidly attaching a protective enclosure to an outer portion of the transformer housing adjacent the secondary terminals. The protective enclosure is configured to enclose the secondary terminals and to house a plurality of electricity meters for measuring electricity usage. The protective enclosure has a plurality of service line apertures sized and shaped to receive a plurality of secondary service lines therethrough. Each secondary service line is electrically connectable to one of the electricity meters. The method also includes installing at least one secondary bus line within the protective enclosure for electrically connecting the secondary terminals to the plurality of electricity meters.

The step of rigidly attaching the protective enclosure to the outer portion of the transformer housing may include providing a meter housing having an interior meter chamber configured for housing the electricity meters, and rigidly attaching a throat to the pre-existing transformer housing and to the meter housing. The meter housing has an opening in a back side thereof, and the throat extends outwardly from the back side of the meter housing around the opening to the outer portion of the transformer housing. The throat is configured to provide an enclosed passageway between the secondary terminals and the interior meter chamber for receiving the secondary bus line therethrough.

The method may also include installing the electricity meters within the protective enclosure and electrically connecting the secondary terminals to the electricity meters using the secondary bus line.

Other aspects and features will become apparent, to those ordinarily skilled in the art, upon review of the following description of some exemplary embodiments.

### BRIEF DESCRIPTION OF THE DRAWINGS

The drawings included herewith are for illustrating various examples of the present specification:

FIG. 1 is a perspective view of an power distribution network including apparatus for deterring theft of electricity according to an embodiment of the present invention;

FIG. 2 is a side perspective view of one of the apparatus of FIG. 1;

FIG. 3 is a front perspective view of the apparatus of FIG. 2;

FIG. 4 is a cross-sectional side elevation view of the apparatus of FIG. 2 along the line 4-4 showing a transformer housing, a metering housing, and a throat therebetween;

FIG. 5 is a cross-sectional top plan view of the apparatus of FIG. 3 along the line 5-5 with the distribution transformer and electricity meters omitted;

FIG. 6 is a cross-sectional front elevation view of the apparatus of FIG. 4 along the line 6-6;

FIG. 7 is a perspective cross-sectional view of the meter housing showing the electricity meters therein;

FIG. 8 is a schematic diagram showing an electricity meter for use with the apparatus of FIG. 2;

FIG. 9 is a side perspective view of an apparatus for deterring theft of electricity according to another embodiment of the present invention;

FIG. 10 is a perspective cross-sectional view of the apparatus of FIG. 9 along the line 10-10; and

FIG. 11 is a flow chart showing a method of refurbishing a pre-existing transformer housing according to another embodiment of the invention.

### DETAILED DESCRIPTION

Referring to FIGS. 1-7, illustrated therein is an apparatus 10 for delivering electricity from a high voltage distribution line to a building. The apparatus 10 is configured and used to deter or protect against theft of electricity. Furthermore, the apparatus 10 is generally used as part of a power distribution network. Specifically, the apparatus 10 may be used when stepping-down a high voltage to a lower voltage. For example, as shown in FIGS. 1-3, the apparatus 10 may be mounted to a utility pole 12 and may be used to step down voltage from a high voltage distribution line 14 to a plurality of lower voltage secondary service lines 16. As shown in FIG. 1, each secondary service line 16 is dedicated to provide electricity to an individual residential or business consumer (e.g. a single building or facility).

With reference to FIG. 4, the apparatus 10 includes a protective enclosure 20 for protecting against theft of electricity from a distribution transformer 22 that is housed within a transformer housing 50. The protective enclosure 20 is rigidly attached to the transformer housing 50 and is configured to house a plurality of electricity meters 24 that are electrically connected to the distribution transformer 22 by a secondary bus line 26 (e.g. which may include wires, busbars, or other electrical conductors). The secondary bus line 26 is located within the enclosure 20. Enclosing the electricity meters 24, and the secondary bus line 26 within the enclosure 20 can inhibit or deter electricity theft by avoiding an “open secondary” between the distribution transformer 22 and the electricity meters 24. As described above, an “open secondary” might otherwise allow unauthorized access to electrical power prior to being measured by the electricity meters 24.

The enclosure 20 is generally made from rigid, high-strength materials that are resistant to being cut, bent, punctured or otherwise deformed. For example, the enclosure 20 may be made from steel such as high-gauge plate steel.

Referring still to FIG. 4, the distribution transformer 22 may be referred to as a “step down” transformer and generally converts electricity from a distribution voltage to a lower secondary voltage. For example, the distribution transformer 22 may convert electricity from distribution voltage of 33 kV to a single-phase, secondary voltage of 120V or 240V. The distribution transformer 22 could also be configured for use with other voltage levels, or other phase configurations such as two-phase or three-phase configurations.

As shown in FIG. 4, the distribution transformer 22 includes a core and coil assembly immersed within a coolant 30 such as oil in order to cool components of the distribution transformer 22. More specifically, the distribution transformer 22 includes a core 31 surrounded by two or more coil windings 32 and 34. For example, a primary winding 32 is connected to the high voltage distribution line 14, which enters the enclosure through a high voltage bushing or terminal 36. A secondary winding 34 is connected to the secondary bus line 26, which transmits the secondary voltage downstream to the electricity meters 24, and then to one or more secondary service lines 16. In other examples, the distribution transformer 22 could have other configurations such a shell-type configuration including two coil windings surrounded by two cores (e.g., as shown in FIG. 10). The distribution transformer 22 could also be a stacked core design, a dry type transformer (e.g. a distribution transformer that is air cooled and does not include a coolant), and the like.

The electricity meters 24 within the protective enclosure 20 measure electricity usage. In this case, the electricity meters 24 are configured to measure electrical power passing through the secondary service lines 16. As shown in FIG. 4, there may be one electricity meter 24 connected to each dedicated secondary service line 16. This can allow the electricity meters 24 to measure the amount of electricity consumed by each residential or business consumer, which can help prevent electricity theft from the utility provider.

The input of each meter 24 is connected to the distribution transformer 22 via the secondary bus line 26. The output of each meter 24 is connected to a respective dedicated secondary service line 16 and exits the enclosure 20 through one or more outlet ports or service line apertures 39. As shown in FIG. 4, the electricity meters 24 may be DIN-style electricity meters mounted to a DIN-rail 38 within the enclosure 20. In other examples, the electricity meters 24 could have other configurations such as socket meters.

Referring still to FIG. 4, the transformer housing 50 defines an interior transformer chamber 40 with the distribution transformer 22 located therein. Furthermore, the protective enclosure 20 defines an interior meter chamber 42 with the electricity meters 24 therein. The protective enclosure 20 also defines an enclosed passageway 44 connecting the interior meter chamber 42 to the interior transformer chamber 42. As shown, the secondary bus line 26 extends from the interior transformer chamber 40, through the enclosed passageway 44, and to the interior meter chamber 42 in order to electrically connect the distribution transformer 22 to the electricity meters 24.

As shown, the interior chambers 40, 42 are created by separate housings. The transformer housing 50 defines the interior transformer chamber 40, and the protective enclosure 20 includes a meter housing 52 defining the interior meter chamber 42. The enclosure 20 also includes a throat 54 rigidly attached to the transformer housing 50 and the meter housing 52. The throat 42 defines the enclosed passageway 44 connecting the interior transformer chamber 42 to the interior meter chamber 42. Using separate housings can provide a number of benefits. For example, the separate housings may help to isolate components of the distribution transformer 22 from the electricity meter 24. This can be particularly helpful when the distribution transformer 22 is immersed within the coolant 30. The separate housings can also allow refurbishing of a pre-existing transformer housing to include the separate meter housing and electricity meters therein.

As shown in the illustrated embodiment, the transformer housing 50 may have a generally cylindrical shape, and the meter housing 52 may have a generally box-like or cuboid shape. Furthermore, the throat 54 may extend from a circumferential outer portion of the transformer housing 50 to a flat outer portion of the meter housing 52. In other examples, the transformer housing 50, meter housing 52, and throat 54 may have other shapes and sizes. For example, the transformer housing 50 may have a rectangular or cuboid shape (e.g., as shown in FIG. 9).

In some examples, the transformer housing 50 may be included as part of the protective enclosure 20. Furthermore, while the illustrated embodiment includes a separate transformer housing 50 and meter housing 52, in other examples, the enclosure 20 may be manufactured as a single housing having the interior transformer chamber 40, the interior meter chamber 42, and the enclosed passageway 44 in a singular unit.

As described above, the secondary bus line 26 is located within the protective enclosure 20 to inhibit or deter electricity theft by avoiding an “open secondary”. For example, with reference to FIGS. 4-7, the secondary bus line 26 extends through the throat 54 between the transformer housing 50 and meter housing 52. As shown, the secondary bus line 26 may be connected to one or more bushings or terminals 56 extending through openings in the transformer housing 50. These terminals 56 may form electrical contact points for wires that electrically connect the distribution transformer 22 to the electricity meters 24. In the illustrated embodiment, there are three low voltage terminals 56 as commonly used with a single-phase, three-wire transformer. In other examples, the number of low voltage terminals 56 may be different depending on the type of transformer used. For example, a three-phase transformer may include four terminals.

After the low voltage terminals 56, the secondary bus line 26 includes cables or wires 57 that extend through the throat 54 and into the meter housing 52. Specifically, as shown in FIG. 4, the back side of the meter housing 52 has an opening 58 for receiving the wires from the throat 54. As shown, the secondary bus line 26 may include one or more busbars 58 for distributing power from the wires 57 to the electricity meters 24. The busbars 58 may be strips of copper or another electrically conductive material that extend vertically within the meter housing 52. In other examples, the wires 57 may be directly connected to each electricity meter 24.

Referring still to FIGS. 4-6, the throat 54 may be rigidly attached to the transformer housing 50 and the meter housing 52 in a number of ways. For example, as shown, the throat 54 may have a first end 60 mounted to the transformer housing 50, and a second end 62 mounted to the meter housing 52. The first end 60 may have a generally concave shape and may be welded to the cylindrically shaped outer portion of the transformer housing 50. The second end 62 may have a flange 64 secured to the flat outer portion of the meter housing 52 using fasteners 66 such as bolts, rivets, and the like. A gasket 68 or another type of seal may be placed between the flange 64 and the meter housing 52. In other examples, the transformer housing 50, meter housing 52, and throat 54 may have other mounting configurations.

As shown in the illustrated embodiment, the throat 54 spaces apart the transformer housing 50 from the meter housing 52. In such cases, the protective enclosure 20 may include one or more support brackets 70 for helping to secure the transformer housing 50 to the meter housing 52. As shown, the support brackets 70 may have a similar length as the throat 54 and are spaced apart from the throat 54. Specifically, there may be two support brackets 70 located below the throat 54. In other examples, the throat 54 itself may be sized and shaped to provide sufficient strength to support the meter housing 52 from the transformer housing 50 without the use of the support brackets 70.

The meter housing 52 also includes a mounting structure for mounting the electricity meters 24 within the interior meter chamber 42. For example, the mounting structure may include a DIN rail 38 supported on a mechanical panel 72 within the meter housing 52. In other examples, there may be another type of mounting structure such as a receptacle for receiving socket-meters.

Referring again to FIGS. 3 and 4, the protective enclosure 20 may include an access door 80 for providing access into the enclosure 20. For example, the access door 80 may be hingedly mounted to the meter housing 52 or another part of the enclosure 20. The access door 80 may be useful when conducting service or maintenance of various components of the apparatus 10 such as the electricity meters 22.

The apparatus 10 may also include an anti-tampering device for restricting unauthorized access through the access door 80. For example, the anti-tampering device may include a lock 82 for closing the access door 80. Additionally or alternatively, the anti-tampering device may include a sensor 84 for detecting unauthorized opening of the access door 80. The sensor 84 may be a proximity sensor such as an optical sensor or a magnetic sensor that detects when the access door 80 is opened. In the event of unauthorized access, the sensor 84 may be configured to trigger an alarm, or shut-off power downstream of the apparatus 10.

Referring now to FIG. 8, each electricity meter 24 may include an automated meter reading device 90 for sending electricity usage information to a remote monitoring service 92. The automated meter reading device 90 may detect the amount of electrical power passing through an electrical line 94 within the electricity meter 24. A processor 96 may then send the electricity usage information to the remote monitoring service using a communication module 98. The communication module 98 may use any suitable form of communication such as power line communication (PLC), radio frequency communication, WIFI communication, or another form of wired or wireless communication. In some examples, the remote monitoring service 92 may be a mobile service such as a handheld wireless device carried by a worker that walks by the meters 24, or a vehicle equipped with a drive-by meter reading device. The remote monitoring service 92 could also be at a fixed location such as a tower, substation, or head office of a utility company. In either case, remotely monitoring electricity usage can track electricity usage and thereby help prevent electricity theft from the utility provider.

Still referring to FIG. 8, each electricity meter 24 may include a disconnect switch 100 such as a relay or another type of switch for disconnecting electrical power downstream of the electricity meter 24. As shown, the disconnect switch 100 may be operatively connected to the automated meter reading device 90 or the remote monitoring service 92 (e.g. via the processor 96). If electricity theft is detected, the disconnect switch 100 may open the electrical line 94, and thereby shut off electrical power downstream of the apparatus 10.

An anti-tampering device 102 (such as the lock 82 or the sensor 84 described above) may be operatively connected to the disconnect switch 100 (e.g. via the processor 96). Accordingly, when the anti-tampering device 102 detects unauthorized opening of the access door 80, the processor 96 may operate the disconnect switch 100 to shut off electrical power downstream of the apparatus 10.

In some examples, the disconnect switch 100 may be separate from the electricity meter 24. For example, the disconnect switch 100 may be included as part of the anti-tampering device 102. Alternatively, the disconnect switch 100 may be an individual component on its own, and in some cases, may be configured to disconnect the high voltage distribution line 14 from the distribution transformer 22.

Referring now to FIGS. 9-10, illustrated therein is another apparatus 110 for delivering electricity from a high voltage distribution line to one or more buildings. The apparatus 110 is similar in some respects to the apparatus 10 and where appropriate similar elements are given similar reference numerals incremented by one hundred. For example, the apparatus 110 includes a protective enclosure 120 for protecting against theft of electricity from a distribution transformer 122 that is housed within a transformer housing 150. Furthermore, the protective enclosure 20 includes a meter housing 152 (e.g., which may be similar to the meter housing 52 described above) and a throat 154 for rigidly attaching the meter housing 152 to the transformer housing 150.

As shown, the transformer housing 150 has a cuboid shape, and the meter housing 152 also has a cuboid shape. Furthermore, the throat 154 extends from a flat outer portion of the meter housing 152 to a flat outer portion of the transformer housing 150. Alternatively, the meter housing 152 may be mounted directly to the transformer housing 150 without use of the throat 154.

With reference to FIG. 10, the distribution transformer 122 within the transformer housing 150 includes a core and coil assembly configured as a shell-type transformer. More specifically, the shell-type distribution transformer 122 includes two cores 131 and 133 that surround a primary winding 132 and a secondary winding 134. In other examples, there may be other numbers of cores and coil windings, for example, depending on the phase or voltages being converted by the transformer.

Referring now to FIG. 11, illustrated therein is a method 200 of refurbishing a pre-existing transformer housing to deter theft of electricity. The method 200 includes steps 210, 220, 230, and 240.

Step 210 includes dismounting the pre-existing transformer housing from a utility pole. The pre-existing transformer housing generally has an interior transformer chamber with a distribution transformer therein, which may be similar to the distribution transformers 22, 122. The pre-existing transformer housing may have a generally cylindrical shape similar to the transformer housing 50, or a cuboid shape similar to the transformer housing 150. The pre-existing transformer could also have other shapes.

The pre-existing transformer housing also has a plurality of secondary terminals extending from the pre-existing transformer housing, such as the bushings or terminals 56 shown in FIGS. 4-7. The secondary terminals of the pre-existing transformer housing are generally connected to secondary service lines for providing electricity to consumers.

Step 220 includes dissembling and removing the distribution transformer from the pre-existing transformer housing. For example, step 220 may include opening the pre-existing transformer housing and removing the transformer coil assembly from the pre-existing transformer housing along with any coolant or oil therein. Paint and other surface coatings may also be removed, for example, by sandblasting the pre-existing transformer housing.

Step 230 includes rigidly attaching a protective enclosure to an outer portion of the transformer housing adjacent the secondary terminals. The protective enclosure is configured to enclose the secondary terminals and to house a plurality of electricity meters for measuring electricity usage. The protective enclosure also has a plurality of service line apertures sized and shaped to receive a plurality of secondary service lines therethrough such as the apertures 39 within the protective enclosure 20 described above.

In some examples, the protective enclosure may include a meter housing such as the meter housings 52 and 152 described above. The meter housing is generally separate from the pre-existing transformer housing. The meter housing may have an interior meter chamber configured to receive one or more of the electricity meters. Furthermore, the meter housing may include a mounting structure for mounting the electricity meters within the interior meter chamber. For example, the mounting structure may include a DIN-rail for receiving DIN-style electricity meters, or one or more receptacles for receiving socket meters.

When the protective enclosure includes a meter housing, step 230 may also include rigidly attaching a throat to the pre-existing transformer housing and to the meter housing. The throat may be similar to one of the throats 54 and 154 described above.

The throat generally defines an enclosed passageway between the secondary terminals and the interior meter chamber for receiving a secondary bus line therethrough. More specifically, the throat may extend outwardly from a back side of the meter housing around an opening therein (such as the opening 58 in the meter housing 50) to the outer portion of the transformer housing adjacent the secondary terminals.

In some examples, the throat may be welded to the pre-existing transformer housing and may be bolted to the meter housing. In other examples, the throat may be attached using other fastening techniques.

When attaching the throat to the pre-existing transformer housing, the throat is generally positioned to overlie the secondary terminals extending from the pre-existing transformer housing. Alternatively, one or more openings may be formed in the pre-existing transformer housing at a location corresponding to the position of the throat, and terminals or bushings may be installed therein. In such cases, the openings may be formed by drilling or cutting away material from the pre-existing transformer housing.

Step 240 includes installing a secondary bus line within the protective enclosure for electrically connecting the secondary terminals to the electricity meters. For example, the secondary bus line may include wires, cables, busbars, and other electrical conductors such as with the secondary bus line 26 described above. Step 240 may also include reassembling the pre-existing transformer housing and reinstalling the distribution transformer therein.

The method 200 may also include step 250 of installing the electricity meters within the protective enclosure and electrically connecting the secondary terminals to the electricity meters using the secondary bus line (e.g. so as to electrically connect the distribution transformer to the electricity meters). The electricity meters may be pre-installed within the meter housing, or may be installed in the field.

One or more of the apparatus and methods described herein can be used to help prevent electricity theft. Specifically, the apparatus and methods can help overcome the problem of theft at “open secondary” lines. One reason for this is that the secondary bus line is enclosed within a protective enclosure. This protective enclosure avoids the existence of open secondary service lines, and thus removes an opportunity for making unauthorized connection to the power distribution network. In addition, the electricity meters can now be located within the enclosure as opposed to being located at the residential or commercial property. This can avoid possible tampering or bypassing of the electricity meters. The enclosure can also include anti-tampering devices for restricting unauthorized access to the enclosure, which can further deter or help prevent tampering of the electricity meters.

While the above description provides examples of one or more apparatus, methods, or systems, it will be appreciated that other apparatus, methods, or systems may be within the scope of the present description as interpreted by one of skill in the art.

1. An apparatus for protecting against theft of electricity from a distribution transformer that transforms electricity from a higher distribution voltage to a lower secondary voltage, the distribution transformer being housed in a transformer housing having secondary terminals extending therefrom, the apparatus comprising:
a) a protective enclosure rigidly attachable to an outer portion of the transformer housing adjacent the secondary terminals, the protective enclosure being configured to enclose the secondary terminals and to house a plurality of electricity meters for measuring electricity usage, the protective enclosure having a plurality of service line apertures sized and shaped to receive a plurality of secondary service lines therethrough, each secondary service line being electrically connectable to one of the electricity meters; and
b) at least one secondary bus line located within the protective enclosure for electrically connecting the secondary terminals to the plurality of electricity meters.

2. The apparatus of claim 1, wherein the protective enclosure comprises:
a) a meter housing having an interior meter chamber configured for housing the electricity meters, and the meter housing having an opening in a back side thereof; and
b) a throat extending outwardly from the back side of the meter housing around the opening to the outer portion of the transformer housing, the throat being configured to provide an enclosed passageway between the secondary terminals and the meter chamber for receiving the secondary bus line therethrough.

3. The apparatus of claim 2, the protective enclosure includes a mounting structure for mounting the plurality of electricity meters within the meter housing.

4. The apparatus of claim 2, wherein the throat spaces apart the transformer housing from the meter housing, and wherein the protective enclosure further comprises a support bracket offset from the throat for securing the transformer housing to the meter housing.

5. The apparatus of claim 2, wherein the throat has a first end mounted to the transformer housing, and a second end with a flange mounted to the meter housing.

6. The apparatus of claim 5, wherein the first end is welded to the transformer housing.

7. The apparatus of claim 5, wherein the flange is secured to the meter housing using fasteners, and wherein the apparatus further comprises a gasket between the second flange and the meter housing.

8. The apparatus of claim 1, wherein the protective enclosure comprises:
a) an access door for providing access to the electricity meters, and
b) an anti-tampering device for restricting unauthorized opening of the access door.

9. The apparatus of claim 8, wherein the anti-tampering device includes a lock for closing the access door.

10. The apparatus of claim 8, wherein the anti-tampering device includes a sensor for detecting unauthorized opening of the access door.

11. The apparatus of claim 8, further comprising a disconnect switch operatively connected to the anti-tampering device, the disconnect switch being configured to disconnect power to a downstream location when the anti-tampering device detects unauthorized opening of the access door.

12. An apparatus for delivering electricity from a high voltage distribution line to a plurality of buildings, the apparatus comprising:
a) a distribution transformer for transforming electricity from a higher distribution voltage to a lower secondary voltage, the distribution transformer being housed in a transformer housing having secondary terminals extending therefrom;
b) a protective enclosure rigidly attachable to an outer portion of the transformer housing adjacent the secondary terminals, the protective enclosure being configured to enclose the secondary terminals and to house a plurality of electricity meters for measuring electricity usage, the protective enclosure having a plurality of service line apertures sized and shaped to receive a plurality of secondary service lines therethrough, each secondary service line being electrically connectable to one of the electricity meters; and
c) at least one secondary bus line located within the protective enclosure for electrically connecting the secondary terminals to the plurality of electricity meters.

13. The apparatus of claim 12, wherein the protective enclosure comprises:
a) a meter housing having an interior meter chamber configured for housing the electricity meters, and the meter housing having an opening in a back side thereof; and
b) a throat extending outwardly from the back side of the meter housing around the opening to the outer portion of the transformer housing, the throat being configured to provide an enclosed passageway between the secondary terminals and the meter chamber for receiving the secondary bus line therethrough.

14. The apparatus of claim 13, wherein the throat spaces apart the transformer housing from the meter housing, and wherein the protective enclosure further comprises a support bracket offset from the throat for securing the transformer housing to the meter housing.

15. The apparatus of claim 13, wherein the throat has a first end mounted to the transformer housing, and a second end with a flange mounted to the meter housing.

16. The apparatus of claim 12, wherein the protective enclosure comprises:
a) an access door for providing access to the electricity meters, and
b) an anti-tampering device for restricting unauthorized opening of the access door.

17. The apparatus of claim 16, wherein the anti-tampering device includes a lock for closing the access door.

18. The apparatus of claim 16, wherein the anti-tampering device includes a sensor for detecting unauthorized opening of the access door.

19. The apparatus of claim 16, further comprising a disconnect switch operatively connected to the anti-tampering device, the disconnect switch being configured to disconnect power to a downstream location when the anti-tampering device detects unauthorized opening of the access door.

20. A method of refurbishing a pre-existing transformer housing to deter theft of electricity, the pre-existing transformer housing having a distribution transformer therein for transforming electricity from a higher distribution voltage to a lower secondary voltage and a plurality of secondary terminals extending from the pre-existing transformer housing, the method comprising:
a) dismounting the pre-existing transformer housing from a utility pole;
b) opening the pre-existing transformer housing and removing the distribution transformer therefrom;
c) rigidly attaching a protective enclosure to an outer portion of the transformer housing adjacent the secondary terminals, the protective enclosure being configured to enclose the secondary terminals and to house a plurality of electricity meters for measuring electricity usage, the protective enclosure having a plurality of service line apertures sized and shaped to receive a plurality of secondary service lines therethrough, each secondary service line being electrically connectable to one of the electricity meters; and
d) installing at least one secondary bus line within the protective enclosure for electrically connecting the secondary terminals to the plurality of electricity meters.

21. The method of claim 20, wherein the rigidly attaching the protective enclosure to the outer portion of the pre-existing transformer housing comprises:
a) providing a meter housing having an interior meter chamber configured for housing the electricity meters, and the meter housing having an opening in a back side thereof; and
b) rigidly attaching a throat to the pre-existing transformer housing and to the meter housing, the throat extending outwardly from the back side of the meter housing around the opening to the outer portion of the transformer housing, the throat being configured to provide an enclosed passageway between the secondary terminals and the interior meter chamber for receiving the secondary bus line therethrough.

22. The method of claim 20, further comprising installing the electricity meters within the protective enclosure and electrically connecting the secondary terminals to the electricity meters using the secondary bus line.
